(19) United States
(12) Patent Application Publication
(10) Pub. No.: US 2021/0381676 A1
(43) Pub. Date: Dec. 9, 2021

(54) A QUANTUM DOT ENHANCED FILM AND A PREPARATION METHOD THEREOF, A BACKLIGHT SOURCE AND A DISPLAY DEVICE

(71) Applicants: Fuzhou BOE Optoelectronics Technology Co., Ltd., Fujian (CN); BOE Technology Group Co., Ltd., Beijing (CN)

(72) Inventor: Guoling FAN, Beijing (CN)

(21) Appl. No.: 16/329,493

(22) PCT Filed: Aug. 15, 2018
(86) PCT No.: PCT/CN2018/100642

§ 371 Date: Feb. 28, 2019

(30) Foreign Application Priority Data
Sep. 30, 2017 (CN) 201710915833.4

(51) Int. Cl. F21V 9/30

(52) U.S. Cl. CPC F21V 9/30; G02F 1/133614

(57) ABSTRACT

The present disclosure provides a quantum dot enhanced film comprising a substrate layer and a functional layer disposed on at least one side in a thickness direction of the substrate layer, wherein the functional layer includes a confining layer and a quantum dot material layer alternately stacked in a thickness direction of the quantum dot enhanced film, the confining layer comprises a hydrotalcite material and/or a hydrotalcite-like material. The present disclosure also provides a backlight source, a preparation method of a quantum dot enhanced film and a display device. When the quantum dot enhanced film is used in a backlight source and/or a display device, a phenomenon of fluorescence quenching is less likely to occur.

### TECHNICAL FIELD

The present disclosure relates to a field of a display device, and in particular to a quantum dot enhanced film, a preparation method of the quantum dot enhanced film, a backlight source including the quantum dot enhanced film, and a display device including the backlight source.

### BACKGROUND

With a development of a display technology, a display device with a quantum dot backlight source has emerged. The quantum dot backlight source includes a quantum dot film. A quantum dot material is provided on the quantum dot film. However, since the quantum dots in an existing quantum dot film have low stability, aggregation of the quantum dot material is likely to occur, and fluorescence quenching occurs, thereby reducing the display effect.

### SUMMARY

The present disclosure provides a quantum dot enhanced film comprising a substrate layer and a functional layer disposed on at least one side in a thickness direction of the substrate layer, the functional layer includes a confining layer and a quantum dot material layer alternately stacked in a thickness direction of the quantum dot enhanced film, the confining layer comprises a hydrotalcite material and/or a hydrotalcite-like material. Optionally, the quantum dot material layer comprises quantum dots.

Optionally, the quantum dot material layer comprises a polyvinyl alcohol substrate and quantum dots dispersed in the polyvinyl alcohol substrate.

Optionally, the functional layer comprises a plurality of the quantum dot material layers and a plurality of the confining layers, and the distance between the two adjacent confining layers is between 5 nm and 10 nm.

Optionally, a layer in the functional layer that is in contact with the substrate layer is a confining layer in the functional layer.

Optionally, a material of the substrate layer is a polyethylene terephthalate.

The present disclosure provides a backlight source comprising a light-emitting element and the quantum dot enhanced film provided in the present disclosure, wherein the quantum dot enhanced film is capable of emitting light when the light-emitting element illuminates the quantum dot enhanced film.

Optionally, the light-emitting element is selected from an LED light source or a laser light source.

The present disclosure provides a display device including a display panel and a backlight source for providing a light source for the display panel, wherein the backlight source is the backlight source provided in the present disclosure.

Optionally, the display panel is selected from a liquid crystal display panel or an electronic paper.

The present disclosure provides a preparation method of a quantum dot enhanced film, comprising the steps of:

providing a substrate layer; and

forming a functional layer on at least one side of the substrate layer to obtain the quantum dot enhanced film, the functional layer includes a confining layer and a quantum dot material layer alternately stacked in a thickness direction of the quantum dot enhanced film, the confining layer comprises a hydrotalcite material and/or a hydrotalcite-like material. Optionally, the quantum dot material layer comprises quantum dots.

Optionally, the step of forming a functional layer on at least one side of the substrate layer comprises a step of forming an initial functional layer and a step of drying the initial functional layer to obtain the functional layer, wherein the step of forming the initial functional layer includes the following alternately performed steps:

disposing a precursor layer formed of a MgAl-LDH nanocolloid solution; and

disposing a quantum dot material layer.

Optionally, the step of disposing a precursor layer comprises:

immersing a first target member in the MgAl-LDH nanocolloid solution for a first predetermined time. The first target member is selected from a substrate layer, or a substrate layer on which a quantum dot material layer and/or a precursor layer is formed.

Optionally, the first predetermined time is 5 minutes to 10 minutes.

Optionally, the step of disposing the quantum dot material layer comprises: immersing a second target member in a polyvinyl alcohol-quantum dot mixed solution for a second predetermined time. The second target member includes at least a substrate layer and a precursor layer formed on the substrate layer.

Optionally, the second predetermined time is 5 minutes to 15 minutes.

### BRIEF DESCRIPTION OF THE FIGURES

The accompanying drawings are intended to provide a further understanding of the disclosure, and form part of the specification. The accompanying drawings are used to explain the present disclosure together with the following specific embodiments, but are not to be construed as limiting.

FIG. 1 is a schematic cross-sectional view of a quantum dot enhanced film provided by some embodiments of the present disclosure;

FIG. 2 is a flow chart of a preparation method of a quantum dot enhanced film provided by some embodiments of the present disclosure; and

FIG. 3 is a schematic illustration of the preparation of a quantum dot enhanced membrane using the preparation method provided in FIG. 2.

DESCRIPTION OF THE REFERENCE NUMERALS

110: a substrate layer 120: a confining layer

131: a quantum dot 132: a polyvinyl alcohol substrate

### DETAILED DESCRIPTION

The specific embodiments of the present disclosure will be described in detail below with reference to the accompanying drawings. It is to be understood that the specific embodiments described herein are only used for illustrating and explaining the present disclosure and are not intended to limit the present disclosure.

As some embodiments of the present disclosure, as shown in FIG. 1, a quantum dot enhanced film is provided, the quantum dot enhanced film includes a substrate layer 110 and a functional layer formed on the substrate layer 110, wherein the functional layer is provided on at least one side in the thickness direction of the base layer 110, and the functional layer includes the confining layer 120 and the quantum dot material layer 130 which are alternately stacked in the thickness direction of the quantum dot enhanced film (in the direction of the arrow in the figure), the confining layer 120 comprises a hydrotalcite material and/or a hydrotalcite-like material, and the quantum dot material layer 130 comprises quantum dots.

A Hydrotalcite material and/or a hydrotalcite-like material are layered bi-metal hydroxides, and thus has a two-dimensional confinement effect. Since the confining layer 120 and the quantum dot material layer 130 are alternately disposed, the confining layer 120 can define a relative distance between the quantum dots in the quantum dot material layer 130 (for example, the distance between the quantum dots can be limited to about 2 nm). Therefore, it is possible to prevent the intermolecular aggregation of the quantum dots in the quantum dot material layer 130, thereby preventing the occurrence of fluorescence quenching.

In the present disclosure, there is no particular limitation on the number of layers of the confining layer 120 and the number of layers of the quantum dot material layer 130 in the functional layer. Although FIG. 1 shows that each functional layer includes two confining layers 120 and two quantum dot material layers 130, the present disclosure is not limited thereto.

In the embodiment shown in FIG. 1, the functional layer is provided on both sides of the substrate layer 110, but the present disclosure is not limited thereto, and the functional layer may be provided only on one side of the substrate layer 110.

Optionally, the quantum dot material layer 130 comprises a polyvinyl alcohol substrate 132 and quantum dots 131 dispersed in the polyvinyl alcohol substrate 132.

In the present disclosure, the polyvinyl alcohol substrate 132 is formed by curing polyvinyl alcohol (PVA). The polyvinyl alcohol substrate 132 has better flexibility and higher strength, so as to support the confining layer 120 and improve a strength of the quantum dot enhanced film.

In the present disclosure, specific requirements are not required for the specific material of the quantum dot. For example, the quantum dot may be a cadmium telluride quantum dot or a quantum dot of other materials.

Quantum dots can include red quantum dots, green quantum dots, and blue quantum dots. When the quantum dots of the three colors are mixed, a white light can be emitted under the illumination of light.

In the present disclosure, the mass percentages of the polyvinyl alcohol substrate 132 and the quantum dot 131 in the quantum dot material layer 130 are not particularly required. Optionally, the mass percentage of quantum dots 131 is greater than zero but less than 0.05% relative to a total mass of the quantum dot material layer 130.

In a preferred embodiment provided by the present disclosure, the quantum dot enhanced film includes a plurality of the quantum dot material layer 130 and a plurality of the confining layers 120.

In a preferred embodiment provided by the present disclosure, the number of layers of the quantum dot material layer 130 in the quantum dot enhanced film is less than 20, and the number of layers of the confining layer 120 in the quantum dot enhanced film is also less than 20.

In order to effectively limit the non-radiative jump of the quantum dots in the quantum dot material layer 130, the quantum yield of the quantum dot enhanced film is increased. Optionally, the distance between the adjacent two confining layers 120 is between 5 nm and 10 nm.

In the present disclosure, in order to avoid aggregation of the quantum dot material in the quantum dot material layer, optionally, a layer in the functional layer that is attached to the substrate layer 110 is a confining layer 120 in the functional layer. All of the quantum dot material layers in the functional layer may be subjected to a space limitation of the confining layer 120, thereby ensuring that quantum dots in all the quantum dot material layers 120 in the functional layer do not undergo aggregation of the quantum dots.

In the present disclosure, no specific requirements are made for the specific material of the substrate layer 110. For example, as a preferred embodiment, the material of the substrate layer 110 is polyethylene terephthalate (PET).

As a second aspect of the present disclosure, a backlight source is provided, wherein the backlight source includes a light-emitting element and the above-described quantum dot enhanced film provided by the present disclosure, and the quantum dot enhanced film is capable of emitting light when the light-emitting element illuminates the quantum dot enhanced film.

In the present disclosure, the light-emitting element may be an LED light source or a laser light source.

The light emitted by the light-emitting element can excite the quantum dot material in the quantum dot enhanced film to emit a colored light, thereby enabling color display. Since the quantum dot enhanced film includes a quantum dot material layer and a confining layer, the quantum dots in the quantum dot material layer are subjected to a two-dimensional confinement of the confining layer, and thus aggregation of the quantum dots does not occur, thereby reducing the probability of fluorescence quenching in the quantum dot enhanced film during luminescence, and improving a display effect of the display device.

In the present disclosure, the specific structure and the specific number of the light-emitting element are also not particularly limited.

As a third aspect of the present disclosure, there is provided a display device including a display panel and a backlight source for providing a light source with the display panel, wherein the backlight source is the backlight source provided by the present disclosure.

As described above, since the fluorescence quenching phenomenon is less likely to occur in the quantum dot enhanced film in the backlight, the light source can be stably provided, so that the display device has a better display effect.

In the present disclosure, the specific structure of the display panel is not specifically limited. For example, the display panel may be a liquid crystal display panel or an electronic paper.

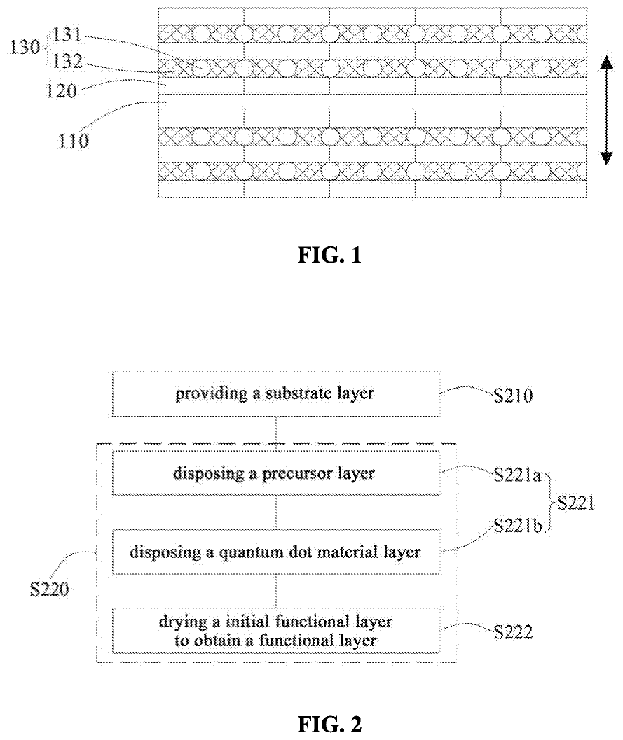

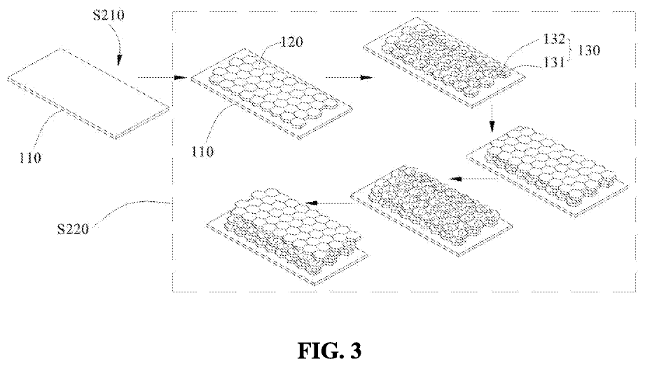

As some embodiments of the present disclosure, a preparation method of a quantum dot enhanced film is provided, wherein, as shown in FIGS. 2 and 3, the preparation method includes the following steps:

providing a substrate layer 110 in step S210; and

forming a functional layer on at least one side of the substrate layer 110 to obtain the quantum dot enhanced film in step S220, the functional layer includes a confining layer 120 and a quantum dot material layer 130 alternately stacked in a thickness direction of the quantum dot enhanced film, the confining layer 120 comprises a hydrotalcite material and/or a hydrotalcite-like material. The quantum dot material layer 130 contains quantum dots.

As described above, the confining layer 120 has a two-dimensional confinement function, which can maintain a distance between the quantum dots of the quantum dot material layer 130 within a predetermined range, thereby preventing aggregation of the quantum dots, and thus effectively preventing fluorescence quenching.

In the present disclosure, there is no particular limitation on how to perform step S220. As a preferred embodiment, the step S220 may include:

in step S221, forming an initial functional layer; and

in step S222, drying the initial functional layer to obtain the functional layer.

Wherein, the step S221 may include the following alternately performed steps:

disposing a precursor layer in step S221a, wherein the precursor layer is formed of a MgAl-LDH nanocolloid solution; and disposing a quantum dot material layer in step S221b.

Since the MgAl-LDH nanocolloid solution is easy to be prepared and is also easily disposed on the substrate layer 110, the step S221 may be realized by a simple method. Therefore, the process difficulty of the entire preparation method is reduced.

The precursor layer may be formed as a confining layer 120 upon solidification.

In the present disclosure, there is no particular requirement on how to dry the initial functional layer. For example, the substrate layer provided with the initial functional layer may be placed in an oven for drying. As a preferred embodiment, the temperature of the drying may be from 80° C. to 90° C., and a time period of the drying may be from 3 hours to 4 hours.

As a preferred implementation, step S221a may specifically include:

immersing a first target member in the MgAl-LDH nanocolloid solution for a first predetermined time

The “first target member” described herein may include only the substrate layer, and may also include a substrate layer on which the quantum dot material layer and/or the precursor layer have been formed.

In the present disclosure, there is no special requirement on the first predetermined time, and optionally, the first predetermined time is 5 minutes to 10 minutes.

In the present disclosure, an MgAl-LDH nanocolloid solution can be obtained commercially, or be prepared by itself. When the self-prepared MgAl-LDH nanocolloid solution is selected, the preparation method comprises a step of providing a MgAl-LDH nanocolloid solution, comprising:

S1, 1.28 g Mg(NO₃)₂.6H₂O, 0.938 g Al(NO₃)₃.9H₂O, and 0.920 g HMT are weighed, and added to a hydrothermal reactor for dissolving in a 50 mL deionized water to obtain a mixture, the hydrothermal reactor is sealed and then placed in oven, and the mixture is reacted at 140° C. for 24 h. The reacted mixture is naturally cooled with an oven, centrifuged for separation, washed three times with deionized water, and dried under vacuum at 40° C. to obtain MgAl—CO₃-LDH;

S2, 0.1 g of MgAl—CO₃-LDH prepared in step S1 is taken, and then added to 800 mL of degassed deionized water to obtain a mixture. After the mixture is sonicated for 30 min, 94.4 g of NaCl is added 24 mL of 0.1 mmol·L⁻¹ hydrochloric acid is added to form a solution. The solution is purged with nitrogen for 5 min, sealed, stirred for 24 h, centrifuged for separation, washed three times with deionized water, and dried under vacuum at 40° C. to obtain MgAl—Cl-LDH;

S3, 0.2 g MgAl—Cl-LDH is weighed, the corresponding amount of 0.05 mol·L⁻¹ NaNO₃ solution and 0.1 mol·L⁻¹ nitric acid solution are taken, and degassed dehydrated water is added to prepare a 200 mL solution. The solution was sonicated for about 30 min, purged with nitrogen for 5 min, sealed, stirred for 24 h, centrifuged for separation, washed three times with deionized water, and dried under vacuum at 40° C. to obtain MgAl—NO₃-LDH;

S4, MgAl—NO₃-LDH is added to the formamide solution for stirring, and the time period for stirring is optionally 24 hours, thereby obtaining a MgAl-LDH nanocolloid solution.

In the present disclosure, there is no special requirement on how to perform step S221b. As a preferred embodiment, step S221b may specifically include immersing a second target member in a polyvinyl alcohol-quantum dot mixed solution for a second predetermined time.

After the second target member is immersed in the polyvinyl alcohol-quantum dot mixed solution, self-assembly occurs forming the quantum dot material layer. In the present disclosure, the second target member includes at least a substrate layer and a precursor layer formed on the substrate layer.

In the present disclosure, there is no particular limitation on the second predetermined time, and optionally, the second predetermined time is 5 minutes to 15 minutes.

It is to be noted that the substrate layer 110 is preferably cleaned using deionized water before the substrate layer 110 which is not provided with any other components is immersed in the MgAl-LDH nanocolloid solution.

After immersing in the MgAl-LDH nanocolloid solution, the substrate layer on which the precursor layer was formed was washed again with deionized water, and then immersed in a polyvinyl alcohol-quantum dot mixed solution.

In some embodiments, as shown in FIG. 3, the preparation method of a quantum dot enhanced film includes the following steps:

in step S210, providing a substrate layer 110; and

in step S220, forming a confining layer 120 on at least one side of the substrate layer 110. Then, a quantum dot material layer 130 is formed on the confining layer 120, and the quantum dot material layer 130 may be formed of a polyvinyl alcohol substrate 132 and quantum dots 131 dispersed in the polyvinyl alcohol substrate 132. The confining layer 120 and the quantum dot material layer 130 may then be sequentially formed on the quantum dot material layer 130. These steps are repeated until the desired number of layers of the confining layer 120 and the quantum dot material layer 130 are obtained. Thereby, a functional layer is formed on at least one side of the substrate layer 110.

As described above, the confining layer 120 has a two-dimensional confinement function, which can maintain the distance between the quantum dots of the quantum dot material layer 130 within a predetermined range, thereby preventing aggregation of quantum dots, and thus effectively preventing fluorescence quenching.

It is to be understood that the above embodiments are merely exemplary embodiments employed to explain the principles of the present disclosure, but the present disclosure is not limited thereto. Various modifications and improvements can be made by those skilled in the art without departing from the spirit and scope of the disclosure, and such modifications and improvements are also considered to be within the scope of the disclosure.

1-15. (canceled)

16. A quantum dot enhanced film comprising a substrate layer and a functional layer disposed on at least one side in a thickness direction of the substrate layer, the functional layer includes a confining layer and a quantum dot material layer alternately stacked in a thickness direction of the quantum dot enhanced film, the confining layer comprises a hydrotalcite material and/or a hydrotalcite-like material.

17. The quantum dot enhanced film according to claim 16, wherein the quantum dot material layer comprises a polyvinyl alcohol substrate and quantum dots dispersed in the polyvinyl alcohol substrate.

18. The quantum dot enhanced film according to claim 16, wherein the functional layer comprises a plurality of the quantum dot material layers and a plurality of the confining layers, and the distance between the two adjacent confining layers is between 5 nm and 10 nm.

19. The quantum dot enhanced film according to claim 17, wherein the functional layer comprises a plurality of the quantum dot material layers and a plurality of the confining layers, and the distance between the two adjacent confining layers is between 5 nm and 10 nm.

20. The quantum dot enhanced film according to claim 16, wherein a layer in the functional layer that is in contact with the substrate layer is the confining layer in the functional layer.

21. The quantum dot enhanced film according to claim 17, wherein a layer in the functional layer that is in contact with the substrate layer is the confining layer in the functional layer.

22. The quantum dot enhanced film according to claim 16, wherein the substrate layer comprises a polyethylene terephthalate.

23. A backlight source comprising a light-emitting element and the quantum dot enhanced film according to claim 16, wherein the quantum dot enhanced film is capable of emitting light when the light-emitting element illuminates the quantum dot enhanced film.

24. The backlight source according to claim 23, wherein the light-emitting element is selected from an LED light source or a laser light source.

25. A display device including a display panel and a backlight source for providing a light source for the display panel, wherein the backlight source is the backlight source according to claim 23.

26. A display device including a display panel and a backlight source for providing a light source for the display panel, wherein the backlight source is the backlight source according to claim 24.

27. The display device according to claim 25, wherein the display panel is selected from a liquid crystal display panel or an electronic paper.

28. A preparation method of a quantum dot enhanced film, comprising the steps of:
providing a substrate layer; and
forming a functional layer on at least one side of the substrate layer to obtain the quantum dot enhanced film, the functional layer includes a confining layer and a quantum dot material layer alternately stacked in a thickness direction of the quantum dot enhanced film, the confining layer comprises a hydrotalcite material and/or a hydrotalcite-like material.

29. The preparation method according to claim 28, wherein the step of forming a functional layer on the substrate layer comprises a step of forming an initial functional layer and a step of drying the initial functional layer to obtain the functional layer, wherein the step of forming the initial functional layer includes the following alternately performed steps:
disposing a precursor layer formed of a MgAl-LDH nanocolloid solution; and
disposing a quantum dot material layer.

30. The preparation method according to claim 29, wherein the step of disposing a precursor layer comprises:
immersing a first target member in the MgAl-LDH nanocolloid solution for a first predetermined time, the first target member is selected from a substrate layer, or a substrate layer on which a quantum dot material layer and/or a precursor layer has been formed.

31. The preparation method according to claim 30, wherein the first predetermined time is 5 minutes to 10 minutes.

32. The preparation method according to claim 29, wherein the step of disposing the quantum dot material layer comprises:
immersing a second target member in a polyvinyl alcohol-quantum dot mixed solution for a second predetermined time, the second target member includes at least a substrate layer and a precursor layer formed on the substrate layer.

33. The preparation method according to claim 30, wherein the step of disposing the quantum dot material layer comprises:
immersing a second target member in a polyvinyl alcohol-quantum dot mixed solution for a second predetermined time, the second target member includes at least a substrate layer and a precursor layer formed on the substrate layer.

34. The preparation method according to claim 31, wherein the step of disposing the quantum dot material layer comprises:
immersing a second target member in a polyvinyl alcohol-quantum dot mixed solution for a second predetermined time, the second target member includes at least a substrate layer and a precursor layer formed on the substrate layer.

35. The preparation method according to claim 32, wherein the second predetermined time is 5 minutes to 15 minutes.
